(19) United States
(12) Patent Application Publication
(10) Pub. No.: US 2024/0379473 A1
(43) Pub. Date: Nov. 14, 2024

(54) PACKAGE STRUCTURE AND FABRICATION METHOD THEREOF, MEMORY SYSTEM AND ELECTRONIC APPARATUS

(71) Applicant: YANGTZE MEMORY TECHNOLOGIES CO., LTD., Wuhan (CN)

(72) Inventors: Peng CHEN, Wuhan (CN); Shanshan ZHAO, Wuhan (CN)

(21) Appl. No.: 18/455,447

(22) Filed: Aug. 24, 2023

(30) Foreign Application Priority Data
May 10, 2023 (CN) 202310528102X

(51) Int. Cl. H01L 23/04; H01L 21/56; H01L 23/29; H01L 23/31

(52) U.S. Cl. CPC H01L 23/04; H01L 21/565; H01L 23/296; H01L 23/3157

(57) ABSTRACT

Examples of the present disclosure disclose a package structure and a fabrication method thereof, a memory system and an electronic apparatus. The package structure includes: a substrate; a first stack structure located on the substrate and including: at least one first chip; a molding layer located on the substrate and encapsulating the first stack structure; and first support structure penetrating the molding layer and located on the periphery of the first stack structure. The first support structure has a height greater than that of the first stack structure.

### CROSS-REFERENCE TO RELATED APPLICATIONS

The present application claims priority to Chinese Patent Application No. 202310528102X, which was filed May 10, 2023, is titled “ENCAPSULATION STRUCTURE AND ITS PREPARATION METHOD, MEMORY SYSTEM AND ELECTRONIC EQUIPMENT,” and is hereby incorporated herein by reference in its entirety.

### TECHNICAL FIELD

Examples of the present disclosure relate to the field of semiconductors, in particular to a package structure and a fabrication method thereof, a memory system and an electronic apparatus.

### BACKGROUND

Substrate designs often focus on satisfying electrical signal connection performance. However, some mobile products propose mechanical strength and toughness requirements for the entire package in addition to the electrical performance.

### SUMMARY

According to the first aspect of the examples of the present disclosure, there is provided a package structure comprising: a substrate; a first stack structure located on the substrate and including at least one first chip; a molding layer located on the substrate and encapsulating the first stack structure; and a first support structure penetrating through the molding layer and located on periphery of the first stack structure; wherein the first support structure has a height greater than that of the first stack structure.

In some examples, at least one of: the first support structure is located on two opposite sides of the first stack structure in a first direction parallel to a plane in which the substrate is located; or the first support structure being located on two opposite sides of the first stack structure in a second direction parallel to the plane in which the substrate is located, wherein the second direction intersects the first direction.

In some examples, when the first support structure is located on two opposite sides of the first stack structure in the first direction, the first support structure have a size in the second direction smaller than or equal to that of the molding layer in the second direction; and when the first support structure is located on two opposite sides of the first stack structure in the second direction, the first support structure have a size in the first direction smaller than or equal to that of the molding layer in the first direction.

In some examples, the first support structure comprises a plurality of first support pillars disposed around the periphery of the first stack structure; and the package structure further comprises: a second stack structure located on the substrate and disposed side by side with the first stack structure, the second stack structure comprising at least one second chip; and a second support structure penetrating through the molding layer and comprising: a plurality of second support pillars disposed around the periphery of the second stack structure, wherein the second support structure has a height greater than that of the second stack structure.

In some examples, the plurality of first support pillars have a first density distribution on the periphery of the first stack structure, the plurality of second support pillars have a second density distribution on the periphery of the second stack structure; wherein the first density distribution and the second density distribution are same or different.

In some examples, the package structure includes a redundancy region and a wiring region; wherein, the first support structure is located in at least one of the redundancy region or the wiring region.

In some examples, the first support structure has a mechanical strength greater than that of the molding layer.

In some examples, the first support structure comprises organic composite material, silicon-based material or metal; and the molding layer comprise epoxy molding material.

According to the second aspect of the examples of the present disclosure, there is provided a fabrication method of a package structure comprising: providing a substrate; forming a first stack structure on the substrate that comprises at least one first chip; forming a molding layer encapsulating the first stack structure on the substrate; and forming a first support structure; wherein the first support structure penetrates through the molding layer and is located on periphery of the first stack structure, the first support structure has a height greater than that of the first stack structure.

In some examples, the forming the first support structure comprises at least one of: forming the first support structure on two opposite sides of the first stack structure in a first direction parallel to a plane in which the substrate is located; or forming the first support structure on two opposite sides of the first stack structure in a second direction parallel to the plane in which the substrate is located, wherein the second direction intersects the first direction.

In some examples, when the first support structure is formed on two opposite sides of the first stack structure in the first direction, the first support structure has a size in the second direction smaller than or equal to that of the molding layer in the second direction; and when the first support structure is formed on two opposite sides of the first stack structure in the second direction, the first support structure has a size in the first direction smaller than or equal to that of the molding layer in the first direction.

In some examples, the forming the first support structure comprises: forming a plurality of first support pillars disposed around the periphery of the first stack structure; wherein the first support structure comprises a plurality of the first support pillars; the fabrication method further comprises: forming a second stack structure disposed side by side with the first stack structure on the substrate, the second stack structure comprising at least one second chip; and forming a second support structure penetrating through the molding layer and comprising: a plurality of second support pillars disposed around the periphery of the second stack structure, the second support structure having a height greater than that of the second stack structure.

In some examples, the plurality of first support pillars have a first density distribution on the periphery of the first stack structure, the plurality of second support pillars have a second density distribution on the periphery of the second stack structure; wherein the first density distribution and the second density distribution are same or different.

In some examples, the package structure includes a redundancy region and a wiring region; the forming the first support structure comprises: forming the first support structure in at least one of the redundancy region or the wiring region.

In some examples, the first support structure has a mechanical strength greater than that of the molding layer.

In some examples, the first support structure comprises organic composite material, silicon-based material or metal; and the molding layer comprise epoxy molding material.

According to the third aspect of the examples of the present disclosure, there is provided a memory system comprising: at least one package structure as described in any one example; and a memory controller coupled to the package structure and configured to control the package structure.

According to the fourth aspect of the examples of the present disclosure, there is provided an electronic apparatus comprising: the memory system as described in the above example; and a host coupled to the memory system.

In an example of the present disclosure, by disposing the first support structure penetrating through the molding layer on periphery of the first stack structure and having a height greater than that of the first stack structure, the first support structure may decentralize external pressure acting on the package structure such that the package structure can deform evenly as a whole to avoid locally large deformation, which facilitates reducing damages to the first stack structure and improving the survival rate of the first stack structure under pressure.

### BRIEF DESCRIPTION OF THE DRAWINGS

FIG. 1 is a diagram of a package structure illustrated according to an example of the present disclosure.

FIG. 2 is a diagram of a package structure illustrated according to an example of the present disclosure.

FIGS. 3(a) and 3(b) are perspective diagrams of a package structure illustrated according to an example of the present disclosure.

FIGS. 4(a) and 4(b) are perspective diagrams of another package structure illustrated according to an example of the present disclosure.

FIG. 5 is a flow diagram of a fabrication method of a package structure illustrated according to an example of the present disclosure.

FIG. 6 is a perspective diagram I of a fabrication process of a package structure illustrated according to an example of the present disclosure.

FIGS. 7(a) and 7(b) are perspective diagrams II of a fabrication process of a package structure illustrated according to an example of the present disclosure.

FIGS. 8(a) and 8(b) are perspective diagrams III of a fabrication process of a package structure illustrated according to an example of the present disclosure.

### DETAILED DESCRIPTION

Technical solutions of the present disclosure will be described in detail further below in connection with the accompanying drawings and examples. Although example implementations of the present disclosure are shown in drawings, the present disclosure may be implemented in various forms rather than being limited to the implementations as set forth herein. In contrast, these implementations are provided to understand the present disclosure more thoroughly and convey the scope of the present disclosure completely to those skilled in the art.

The present disclosure will be described in more detail in the following paragraphs with reference to figures illustratively. The advantages and features of the present disclosure will become clearer according to the following description and claims. The drawings are all in simplified form and in non-precise scale, and they are only for the purpose of illustrating examples of the present disclosure in a convenient and clear way.

Terms “first”, “second” etc. in examples of the present disclosure are used to distinguish similar objects and not necessarily to describe particular order or sequential order.

Technical solutions of examples of the present disclosure may be combined arbitrarily if there is no conflict.

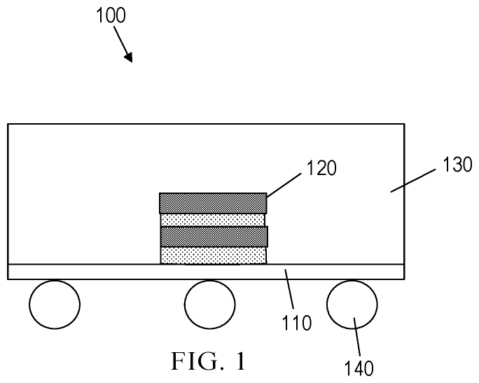

FIG. 1 is a diagram of a package structure 100 illustrated according to an example. Referring to FIG. 1, the package structure 100 includes a substrate 110, a first stack structure 120, a molding layer 130 and a plurality of solder balls 140. The first stack structure 120 is located on the substrate 110 and includes a plurality of stacked chips. The molding layer 130 is located on the substrate 110 and encapsulates the first stack structure 120. The solder balls 140 are located on a surface of the substrate 110 away from the molding layer 130 and connected with the plurality of chips in the first stack structure 120 via the wiring layer (not shown) in the substrate 110.

When the package structure 100 is subject to a force, the package structure 100 would undergo mechanical deformation that may damage chips in the package structure 100, reducing the survival rate of the package structure 100.

One solution is thinning the chip thickness to enhance the toughness of the package. However, thinning the chip would increase the packaging difficulty and reduce the yield. Another solution is to enhance the deformation capability of the chips themselves by improving fabrication process. However, improving fabrication process may be challenging and expensive.

In view of this, examples of the present disclosure provide a package structure and a fabrication method thereof, a memory system and an electronic apparatus.

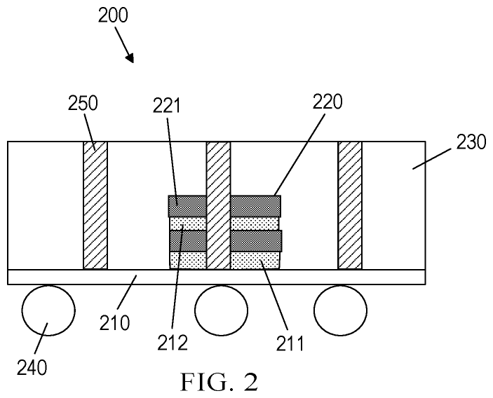

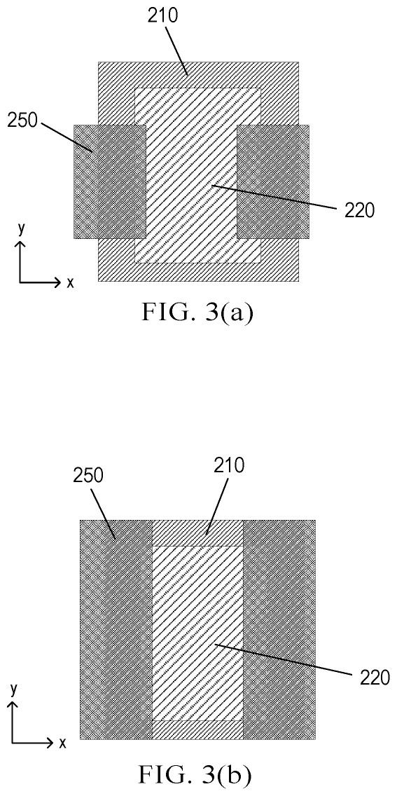

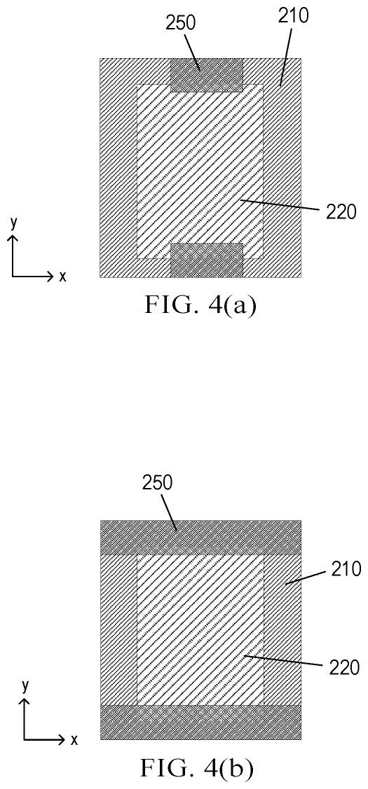

FIG. 2 is a diagram of a package structure 200 illustrated according to an example of the present disclosure. FIGS. 3(a) and 3(b) are perspective diagrams of a package structure 200 illustrated according to an example of the present disclosure, and may be collectively referred to as FIG. 3. FIGS. 4(a) and 4(b) are perspective diagrams of another package structure 200 illustrated according to an example of the present disclosure, and may be collectively referred to as FIG. 4. The package structure 200 provided in examples of the present disclosure will be described in detail below with reference to FIGS. 2, 3 and 4. Referring to FIG. 2, the package structure 200 includes: a substrate 210; a first stack structure 220 on the substrate 210 and including at least one first chip 221; a molding layer 230 on the substrate 210 and encapsulating the first stack structure 220; and a first support structure 250 penetrating through the molding layer 230 and located on periphery of the first stack structure 220. The first support structure 250 has a height greater than that of the first stack structure 220.

The substrate 210 may be a circuit board with wiring circuits, or a substrate formed from silicon, ceramics, glass, or other material. In some examples, the substrate 210 has a plurality of structures disposed thereon for forming electrical connection such as pad structures on the upper surface of the substrate 210 (not shown), contact structures on the lower surface of the substrate 210 (not shown) and wire structures between the upper surface and lower surface of the substrate 210 (not shown) etc.

The first stack structure 220 includes at least one first chip 221 stacked one on another and the first chip 221 is electrically connected with the substrate 210 for electrical signal transmission. The first chip 221 includes, but is not limited to a memory chip such as a static random access memory, a dynamic random access memory, a read-only memory or a flash memory etc. In other examples, the first chip 221 may also be a processor chip, a sensor chip, a power source chip, a communication chip, or an interface chip.

Here, the number of the first chip 221 may be one or more. When a plurality of first chips 221 are stacked, at least two first chips 221 in the plurality of first chips 221 may have the same or different types and/or sizes, which is not limited herein.

In some examples, the first stack structure 220 further includes first bonding layers 212 between two adjacent first chips 221. The plurality of first chips 221 are bonded via the first bonding layers 212 for stacking. In other examples, the plurality of first chips 221 may be stacked by hybrid bonding.

In some examples, the package structure 200 further includes a second bonding layer 211 between the first stack structure 220 and the substrate 210. The first stack structure 220 is fixed on the substrate 210 via the second bonding layer 211. In other examples, the first stack structure 220 may also be fixed on the substrate 210 by flip-chip bonding.

The first bonding layer 212 and the second bonding layer 211 include, but is not limited to die attach film (DAF). The materials for the first bonding layer 212 and the second bonding layer 211 may be the same or different, which is not limited herein.

The material for the molding layer 230 includes epoxy molding material such as epoxy resin film molding material, biphenyl type epoxy resin, silicon-containing epoxy resin or fluorine-containing epoxy resin. The molding layer 230 is configured to protect the first stack structure 220 to prevent the first stack structure 220 from contacting external environments, avoiding physical damage or corrosion of the first stack structure 220.

In an example, in the direction perpendicular to the plane in which the substrate 210 is located, the first support structure 250 has a height greater than that of the first stack structure 220, and the first support structure 250 has a height equal to the height of the molding layer 230, namely the first support structure 250 is flush with the molding layer 230. In the example, the first support structure 250 and the molding layer 230 may together decentralize external pressure acting on the package structure 200, such that the package structure 200 can deform evenly as a whole to avoid locally large deformation, which facilitates reducing damages to the first stack structure 220.

In yet another example, in the direction perpendicular to the plane in which the substrate 210 is located, the first support structure 250 has a height greater than that of the first stack structure 220, and the first support structure 250 has a height greater than that of the molding layer 230, namely the first support structure 250 is raised with respect to the molding layer 230. In the present example, the first support structure 250 may decentralize external pressure acting on the package structure 200, such that the package structure 200 can deform evenly as a whole to avoid locally large deformation, which facilitates reducing damages to the first stack structure.

In some examples, the package structure 200 further includes a plurality of solder balls 240 located on a surface of the substrate 210 away from the molding layer 230 and connected with the first chips 221 via the wiring layer in the substrate 210.

In an example of the present disclosure, by disposing the first support structure penetrating through the molding layer on periphery of the first stack structure and having a height greater than that of the first stack structure, the first support structure may decentralize external pressure acting on the package structure, such that the package structure can deform evenly as a whole to avoid locally large deformation, which facilitates reducing damages to the first stack structure and improving the survival rate of the first stack structure under pressure.

In some examples, at least one of: the first support structure being located on two opposite sides of the first stack structure in the first direction that is parallel to the plane in which the substrate is located; or the first support structure is located on two opposite sides of the first stack structure in the second direction that is parallel to the plane in which the substrate is located, wherein the second direction intersects the first direction.

In an example, referring to FIG. 3, the first support structure 250 is on two opposite sides of the first stack structure 220 in x direction, and by disposing the first support structure 250 on two sides of the first stack structure 220, it is possible to evenly decentralize external pressure acting on the package structure 200.

In another example, referring to FIG. 4, the first support structure 250 is on two opposite sides of the first stack structure 220 in y direction, and by disposing the first support structure 250 on two sides of the first stack structure 220, it is possible to evenly decentralize external pressure acting on the package structure 200.

In yet another example, the first support structure 250 is on two opposite sides of the first stack structure 220 in x direction and two opposite sides in y direction, and by disposing the first support structure 250 on the periphery of the first stack structure 220 to form a cage-like first support structure, it is possible to more evenly decentralize external pressure acting on the package structure 200.

In an example, at least one of: the first support structure 250 on two opposite sides in x direction being axially symmetrical about the central axis of the first stack structure 220; or the first support structure 250 on two opposite sides in y direction being axially symmetrical about the central axis of the first stack structure 220.

The first direction and the second direction as used herein represent x direction and y direction respectively, the first direction and the second direction are both parallel to the plane in which the substrate 210 is located. The first direction intersects the second direction, and the angle between the first direction and the second direction includes acute angle, right angle, or obtuse angle, which is not limited herein.

In an example of the present disclosure, by at least one of: disposing the first support structure on two opposite sides of the first stack structure in the first direction or disposing the first support structure on two opposite sides of the first stack structure in the second direction, it is possible to evenly decentralize external pressure acting on the package structure, such that the package structure can deform evenly as a whole, thereby avoiding damages to the first stack structure due to locally large deformation.

In some examples, when the first support structure is located on two opposite sides of the first stack structure in the first direction, the first support structure has a size in the second direction smaller than or equal to that of the molding layer in the second direction.

In an example, referring to FIG. 3(a), the first support structure 250 is located on two opposite sides of the first stack structure 220 in x direction, have a size in y direction smaller than that of the molding layer 230 in y direction, and can provide local support but do not occupy excess area of the substrate 210.

In an example, referring to FIG. 3(b), the first support structure 250 is located on two opposite sides of the first stack structure 220 in x direction, have a size in y direction equal to that of the molding layer 230 in y direction, and can provide global support to decentralize external pressure more evenly.

In some examples, when the first support structure is located on two opposite sides of the first stack structure in the second direction, the first support structure has a size in the first direction smaller than or equal to that of the molding layer in the first direction.

In an example, referring to FIG. 4(a), the first support structure 250 is located on two opposite sides of the first stack structure 220 in y direction, have a size in x direction smaller than that of the molding layer 230 in x direction, and can provide local support but do not occupy excess area of the substrate 210.

In another example, referring to FIG. 4(b), the first support structure 250 is located on two opposite sides of the first stack structure 220 in y direction, have a size in x direction equal to that of the molding layer 230 in x direction, and can provide global support to decentralize external pressure more evenly.

In some examples, the first support structure 250 includes a plurality of first support pillars disposed around the periphery of the first stack structure 220, and the package structure 200 further includes:
a second stack structure on the substrate 210 and disposed side by side with the first stack structure 220, including at least one second chip; and
a second support structure penetrating through the molding layer 230 and including: a plurality of second support pillars disposed around the periphery of the second stack structure, wherein the second support structure has a height greater than that of the second stack structure.

In some examples, a plurality of first support pillars are disposed on the periphery of the first stack structure and spacings between two adjacent first support pillars are greater than or equal to 0. Herein, the spacings between two adjacent first support pillars may be the same or different, which is not limited herein.

The second stack structure includes at least one second chip stacked that is electrically connected with the substrate 210 for electrical signal transmission. The second chip includes, but is not limited to a memory chip such as a static random access memory, a dynamic random access memory, a read-only memory or a flash memory etc. In other examples, the second chip may also be a processor chip, a sensor chip, a power source chip, a communication chip or an interface chip.

Herein, the number of the second chip may be one or more. When a plurality of second chips are stacked, at least two second chips in the plurality of second chips may have the same or different types and/or sizes, which is not limited herein.

In some examples, the second stack structure further includes third bonding layers between two adjacent second chips. The plurality second chips are bonded via the third bonding layers for stacking. In other examples, the plurality of second chips may be stacked by hybrid bonding.

In some examples, the package structure 200 further includes a fourth bonding layer between the second stack structure and the substrate 210. The second stack structure is fixed on the substrate 210 via the fourth bonding layer. In other examples, the second stack structure may also be fixed on the substrate 210 by flip-chip bonding.

The third bonding layer and the fourth bonding layer include, but is not limited to die attach film (DAF). The materials for the first bonding layer, the second bonding layer, the third bonding layer and the fourth bonding layer may be the same or different, which is not limited herein.

In an example, in the direction perpendicular to the plane in which the substrate 210 is located, the second support structure has a height greater than that of the second stack structure, and the second support structure has a height equal to the height of the molding layer 230, namely the second support structure is flush with the molding layer 230. In the example, the second support structure and the molding layer 230 may together decentralize external pressure acting on the package structure 200 such that the package structure 200 can deform evenly as a whole to avoid locally large deformation, which facilitates reducing damages to the second stack structure.

In another example, in the direction perpendicular to the plane in which the substrate 210 is located, the second support structure has a height greater than that of the second stack structure, and the second support structure has a height greater than that of the molding layer 230, namely the second support structure is raised with respect to the molding layer 230. In the example, the second support structure may decentralize external pressure acting on the package structure 200 such that the package structure 200 can deform evenly as a whole to avoid locally large deformation, which facilitates reducing damages to the second stack structure.

In some examples, a plurality of second support pillars are disposed on the periphery of the second stack structure and spacings between two adjacent second support pillars are greater than or equal to 0. Herein, the spacings between two adjacent second support pillars may be the same or different, which is not limited herein.

The sectional shapes of the first support pillars and the second support pillars include circular, triangular, rectangular, or other polygonal shapes. Herein, the sectional shapes of the plurality of first support pillars may be the same or different, the sectional shapes of the plurality of second support pillars may be the same or different, and the sectional shapes of the first support pillars and the second support pillars may be the same or different, which is not limited herein.

In some examples, the plurality of first support pillars have a first density distribution on the periphery of the first stack structure 220, the plurality of second support pillars have a second density distribution on the periphery of the second stack structure; wherein the first density distribution and the second density distribution may be the same or different.

In an example, the first stack structure 220 has a pressure-bearing capability smaller than that of the second stack structure, and the first density distribution is greater than the second density distribution.

In another example, the first stack structure 220 has a pressure-bearing capability greater than that of the second stack structure, and the first density distribution is smaller than the second density distribution.

In yet another example, the first stack structure 220 has a pressure-bearing capability equal to the pressure-bearing capability of the second stack structure, and the first density distribution is equal to the second density distribution.

Herein, the magnitudes of the first density distribution and the second density distribution may be represented by the numbers of the first support pillars and the second support pillars in the same area or the areas occupied by the same number of first support pillars and second support pillars. For example, if the number of first support pillars in the same area is greater than the number of second support pillars, the first density distribution is greater than the second density distribution.

In examples of the present disclosure, it is possible to integrate a plurality of stack structures on the substrate to increase the integration level of the package structure and support pillars of different density distributions are disposed according to pressure-bearing capabilities of different stack structures to decentralize external pressure reasonably.

In some examples, the package structure 200 includes a redundancy region and a wiring region, wherein the first support structure is located in at least one of the redundancy region or the wiring region.

In an example, the redundancy region includes corner regions on the substrate 210, and the first support structure 250 is located in the redundancy region such that the first support structure 250 evenly decentralizes the external pressure without occupying excess area of the substrate 210.

In another example, partial spaces are left by optimizing layout of the wiring region and the first support structure 250 is disposed in the spaces. Since the wiring region is closer to the first stack structure 220, the effect of decentralizing pressure on the package structure 200 by the first support structure 250 is enhanced, which further protects the first stack structure 220 without occupying excess area of the substrate 210.

In yet another example, the first support structure 250 is located in the redundancy region and the wiring region, such that the effect of decentralizing pressure on the package structure 200 by the first support structure 250 is further enhanced, which even further protects the first stack structure 220 without occupying excess area of the substrate 210.

In some examples, the ratio of the orthographic projection area of the first support structure 250 to the orthographic projection area of the substrate 210 is 3% to 7%. In an example, the ratio of the orthographic projection area of the first support structure 250 to the orthographic projection area of the substrate 210 is 5%.

In examples of the present disclosure, by disposing the first support structure in at least one of the redundancy region or wiring region of the package structure, the at least one of the redundancy region or wiring region of the package structure is utilized reasonably and external pressure is evenly decentralized without occupying excess area of the substrate.

In some examples, the first support structure 250 has a mechanical strength greater than that of the molding layer 230. By disposing the first support structure 250 with greater mechanical strength in the molding layer 230, it is possible to provide better support and avoid locally large deformation.

In some examples, the first support structure 250 includes organic composite material, silicon-based material or metal; and the molding layer includes epoxy molding material.

In some examples, the organic composite material includes polystyrene, polymethyl methacrylate or polypropylene family high molecular material; the silicon-based material includes carbon-coated silicon monoxide, nano-silicon carbide, amorphous silicon alloy or silicon nanowire; and the metal includes copper, aluminum or the like.

In an example, the same external force of 80N is applied, the deformation amount of the stack structure in the package structure provided with support structure is 1975ue, and the deformation amount of the stack structure in the package structure without the support structure is 2060ue. The deformation amount of the stack structure is reduced after providing the support structure on periphery of the stack structure.

Based on the above-described package structure, an example of the present disclosure further provides a fabrication method of a package structure.

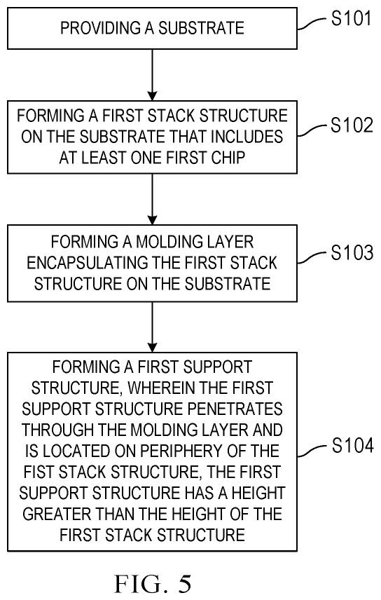

FIG. 5 is a flow diagram of a fabrication method of a package structure illustrated according to an example of the present disclosure. Referring to FIG. 5, the fabrication method includes at least the following operations:
S101: providing a substrate;
S102: forming a first stack structure on the substrate that includes at least one first chip;
S103: forming a molding layer encapsulating the first stack structure on the substrate; and
S104: forming a first support structure; wherein the first support structure penetrates through the molding layer and is located on periphery of the first stack structure, the first support structure has a height greater than that of the first stack structure.

The operations shown in FIG. 5 is not exclusive and other operations may be executed before, after or among any operations in the shown operations. Operations shown in FIG. 5 may be adjusted in terms of order as practical demands.

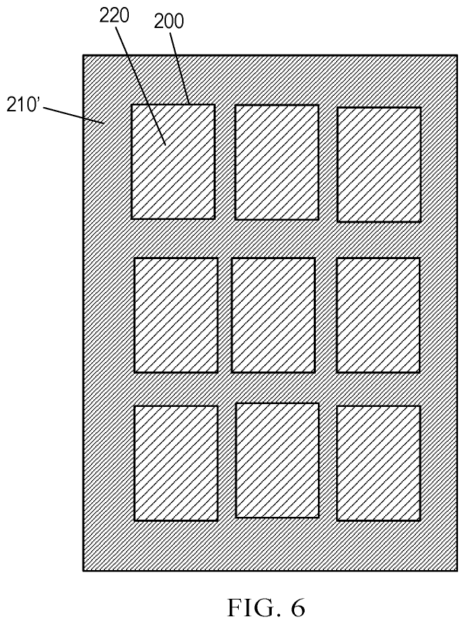

FIGS. 6 to 8 are perspective diagrams of a fabrication process of a package structure illustrated according to an example of the present disclosure. The fabrication method of the package structure as provided in examples of the present disclosure will be described in detail below with reference to FIGS. 2 and 5 to 8.

In operation S101, referring to FIG. 6, a substrate 210′ is provided. The substrate 210′ may be a circuit board with wiring circuits, or a substrate formed from silicon, ceramics, glass or other material. In some examples, the substrate 210′ has a plurality of structures for forming electrical connection, such as pad structures on the upper surface of the substrate 210′ (not shown), contact structures on the lower surface of the substrate 210′ (not shown) and wire structures inside the substrate 210′ (not shown) etc.

In operation S102, as shown in FIGS. 2 and 6, a first stack structure 220 is formed on the substrate 210′ that includes at least one first chip 221.

In some examples, the one or more first chips 221 may be bonded with the substrate 210′ successively via adhesive for stacking, and the first chips 221 may be electrically connected with the substrate 210′ via leads. Herein, at least two first chips 221 may be bonded first to constitute the first stack structure 220, and the first stack structure 220 is then bonded with the substrate 210′. Alternatively, one or more first chips 221 may be bonded successively on the substrate 210′ to form the first stack structure 220 on the substrate 210′.

When the first stack structure 220 includes more than two first chips 221, the adhesive between adjacent two first chips 221 is labeled as the first bonding layer 212, and the adhesive between the bottom layer of first chips 221 and the substrate 210′ is labeled as the second bonding layer 211.

In some other examples, the one or more first chips 221 are bonded with the substrate 210′ via hybrid bonding and flip-chip bonding for stacking, and the first chips 221 may be electrically connected with the substrate 210′ via at least one of bumps, contact pads and through-silicon via structures. Here, it is possible to hybrid bond at least two first chips 221 to constitute the first stack structure 220, and then flip-chip bond the first stack structure 220 and the substrate 210′.

In operation S103, as shown in FIGS. 2 and 6, a molding layer 230 is formed on the substrate 210′ that encapsulates the first stack structure 220. Herein, the molding layer 230 may be formed by injecting molding material, and performing processes of such as drying, shaping, and curing on the material.

The molding material includes epoxy molding material such as epoxy resin film molding material, biphenyl type epoxy resin, silicon-containing epoxy resin or fluorine-containing epoxy resin. The molding layer 230 is configured to protect the first stack structure 220 to prevent the first stack structure 220 from contacting external environments, avoiding physical damage or corrosion of the first stack structure 220.

In operation S104, referring to FIG. 2, the first support structure 250 is formed, wherein the first support structure 250 penetrates through the molding layer 230 and is located on periphery of the first stack structure 220, the first support structure 250 has a height greater than that of the first stack structure 220.

In some examples, vias penetrating through the molding layer 230 are formed by etching process. The substrate 210′ is exposed at the bottoms of vias and support material is filled in the vias to form the first support structure 250.

In some other examples, a sacrificial layer covering the substrate 210′ is formed, and vias penetrating through the sacrificial layer are formed by etching process. The substrate 210′ is exposed at the bottoms of vias and support material is filled in the vias to form the first support structure 250. Then the sacrificial layer is removed and molding material is filled to form the molding layer 230.

The etching process includes any one of dry etching, wet etching or combinations thereof.

In some examples, the first support structure 250 has a mechanical strength greater than that of the molding layer 230. By disposing the first support structure 250 with greater mechanical strength in the molding layer 230, it is possible to provide better support and avoid locally large deformation.

In some examples, when the first support structure is formed on two opposite sides of the first stack structure in the first direction, the first support structure have a size in the second direction smaller than or equal to that of the molding layer in the second direction.

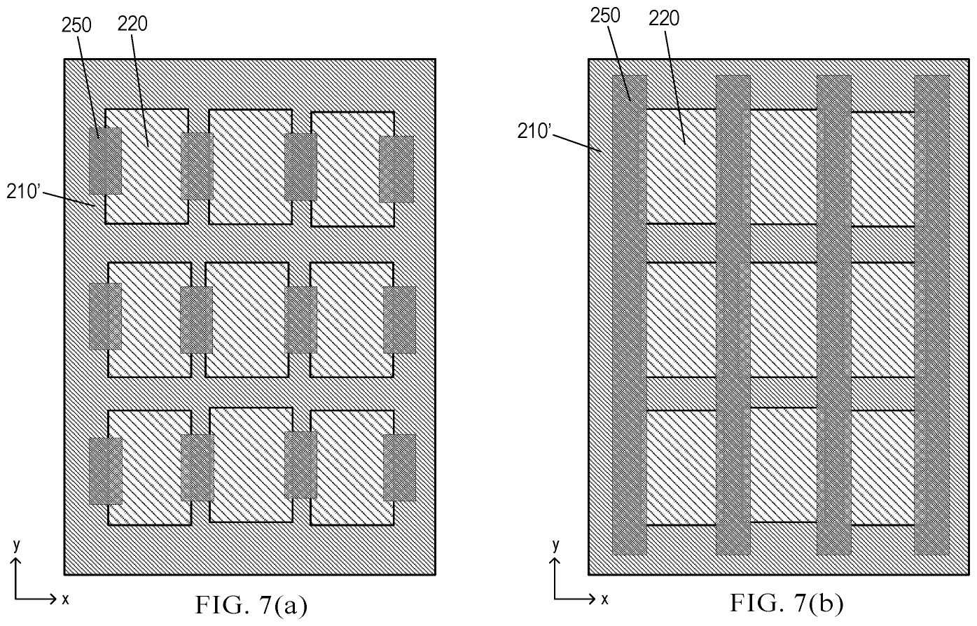

In an example, referring to FIG. 7(a), vias are formed on two opposite sides of the first stack structure 220 in x direction in which the vias have a size in y direction smaller than that of the molding layer 230 in y direction. The support material is filled in the vias for forming the first support structure 250 in subsequent processes.

In an example, referring to FIG. 7(b), vias are formed on two opposite sides of the first stack structure 220 in x direction in which the vias have a size in y direction equal to that of the molding layer 230 in y direction. The support material is filled in the vias for forming the first support structure 250 in subsequent processes.

In an example, the substrate 210′ includes cutting lines, and a plurality of package structures 200 may be obtained by cutting along the extending direction of the cutting lines. The substrate 210′ located in the package structure 200 after cutting constitutes the substrate 210. The size of the molding layer 230 refers to the size of the molding layer 230 located on the substrate 210.

In some examples, when the first support structure is formed on two opposite sides of the first stack structure in the second direction, the first support structure has a size in the first direction smaller than or equal to that of the molding layer in the first direction.

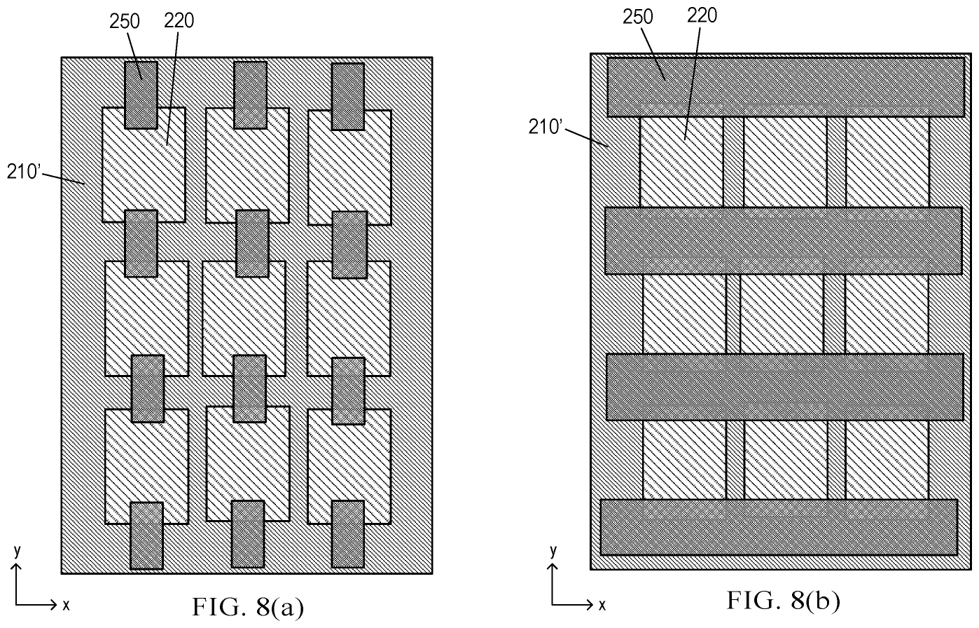

In an example, referring to FIG. 8(a), vias are formed on two opposite sides of the first stack structure 220 in y direction in which the vias have a size in x direction smaller than that of the molding layer 230 in x direction. The support material is filled in the vias for forming the first support structure 250 in subsequent processes.

In an example, referring to FIG. 8(b), vias are formed on two opposite sides of the first stack structure 220 in y direction, in which the vias have a size in x direction equal to that of the molding layer 230 in x direction. The support material is filled in the vias for forming the first support structure 250 in subsequent processes.

In some examples, the above-described operation S104 includes: forming a plurality of first support pillars disposed around the periphery of the first stack structure 220; wherein the first support structure 250 includes a plurality of first support pillars.

In some examples, the above-described fabrication method further includes: forming the second stack structure disposed side by side with the first stack structure 220 on the substrate 210′, the second stack structure including at least one second chip; and

forming a second support structure penetrating through the molding layer 230 and including: a plurality of second support pillars disposed around the periphery of the second stack structure, the second support structure having a height greater than that of the second stack structure.

In some examples, a plurality of vias are formed on the periphery of the first stack structure 220 and spacings between two adjacent vias are greater than or equal to 0. The support material is filled in the plurality of vias respectively to form a plurality of first support pillars. Herein, the spacings between two adjacent vias may be the same or different, and the support material filled in at least two vias may be the same or different.

Herein, the method for forming the second stack structure is similar to the above-described method for forming the first stack structure 220, and the method for forming the second support structure is similar to the above-described method for forming the first support structure, which will not be described again herein.

In some examples, the plurality of first support pillars have a first density distribution on the periphery of the first stack structure, the plurality of second support pillars have a second density distribution on the periphery of the second stack structure; wherein the first density distribution and the second density distribution may be the same or different.

In an example, the first stack structure has a pressure-bearing capability smaller than that of the second stack structure, and the first density distribution is greater than the second density distribution.

In another example, the first stack structure has a pressure-bearing capability greater than that of the second stack structure, and the first density distribution is smaller than the second density distribution.

In yet another example, the first stack structure has a pressure-bearing capability equal to the pressure-bearing capability of the second stack structure, and the first density distribution is equal to the second density distribution.

Herein, the magnitudes of the first density distribution and the second density distribution may be represented by the numbers of the first support pillars and the second support pillars formed in the same area, or by the areas occupied by forming the same number of first support pillars and second support pillars. For example, if the number of first support pillars formed in the same area is greater than the number of the formed second support pillars, the first density distribution is greater than the second density distribution.

In some examples, referring to FIG. 2, the above-described fabrication method further includes: forming a plurality of solder balls 240 on a surface of the substrate 210 away from the molding layer 230, the plurality of solder balls 240 connected with the first chip 221 via the wiring layer in the substrate 210.

In some examples, the package structure 200 includes a redundancy region and a wiring region, and the above-described operation S104 includes forming the first support structure 250 in at least one of the redundancy region or the wiring region. Herein, by forming the first support structure 250 in at least one of the redundancy region or the wiring region, the first support structure 250 decentralizes pressure acting on the package structure 200 evenly without occupying excess area of the substrate 210′, thereby avoiding locally large deformation.

Based on the above-described package structure 200, an example of the present disclosure further provides a memory system including:
at least one package structure 200 as described above in any example; and
a memory controller coupled to the package structure 200 and configured to control the package structure 200.

The memory system includes a mobile phone, a laptop computer, a tablet, a vehicle computer, a gaming console, a printer, a positioning device, a wearable electronic device, a smart sensor, a virtual reality (VR) device, an argument reality (AR) device, or any other suitable electronic devices having memory therein.

In some examples, the memory controller is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc.

In some other examples, the memory controller is designed to operate in high duty cycle environment solid state disks (SSDs) or embedded multimedia cards (eMMCs) that are used as e.g., data storages and enterprise memory arrays of the mobile devices such as smart phones, tablet computers and laptop computers.

The memory controller can be configured to control operations of the package structure, such as read, erase, and program operations. The memory controller can also be configured to manage various functions with respect to the data stored or to be stored in the package structure including, but is not limited to bad-block management, garbage collection, logical-to-physical address conversion, wear leveling, etc. In some implementations, the memory controller is further configured to process error correction codes (ECCs) with respect to the data read from or written to the package structure.

Any other suitable functions may be performed by the memory controller as well, for example, formatting the memory. The memory controller can communicate with an external device (e.g., the host) according to a particular communication protocol. For example, the memory controller may communicate with the external device through at least one of various interface protocols, such as a USB protocol, an MMC protocol, a peripheral component interconnection (PCI) protocol, a PCI-express protocol, an advanced technology attachment protocol, a serial protocol, a parallel protocol, a small computer small interface protocol, an enhanced small disk interface protocol, an integrated drive electronics protocol, a Firewire protocol, etc.

The memory controller and one or more package structures may be integrated into various types of storage devices.

In other examples, the memory controller may be encapsulated in the molding layer together with the first stack structure, and then the package structure may serve as the memory system.

Based on the above-described memory system, an example of the present disclosure further provides an electronic apparatus including:
the memory system as described in the above example; and
a host coupled to the memory system.

The electronic apparatus includes a mobile phone, a desktop computer, a tablet computer, a notebook computer, a server, an on-vehicle device, a wearable device or a mobile power source, etc.

The host can be a processor of an electronic device, such as a central processing unit (CPU), or a system-on-chip (SoC), such as an application processor (AP). The host may be configured to send data to the memory. Alternatively, the host may be configured to receive data from the memory.

What have been described above are only implementations of the present disclosure.

However, the scope of the present disclosure is not limited thereto, and variations or substitutions that easily occur to one skilled in the art in the scope disclosed in the present disclosure should be encompassed in the scope of the present disclosure. Therefore, the scope of the present disclosure should be determined by the scope of the claims.

What is claimed is:

1. A package structure, comprising:
a substrate;
a first stack structure located on the substrate and including at least one first chip;
a molding layer located on the substrate and encapsulating the first stack structure; and
a first support structure penetrating through the molding layer and located on periphery of the first stack structure, wherein the first support structure has a height greater than that of the first stack structure.

2. The package structure of claim 1, wherein:
the first support structure is located on two opposite sides of the first stack structure in a first direction parallel to a plane in which the substrate is located.

3. The package structure of claim 2, wherein,
the first support structure has a size in a second direction smaller than or equal to that of the molding layer in the second direction, wherein the second direction intersects the first direction.

4. The package structure of claim 2, wherein:
the first support structure is located on two opposite sides of the first stack structure in a second direction parallel to the plane in which the substrate is located, and
wherein the second direction intersects the first direction.

5. The package structure of claim 4, wherein,
the first support structure is located on two opposite sides of the first stack structure in the second direction, the first support structure has a size in the first direction smaller than or equal to that of the molding layer in the first direction.

6. The package structure of claim 1, wherein the first support structure comprises a plurality of first support pillars disposed around the periphery of the first stack structure; and the package structure further comprises:
a second stack structure located on the substrate and disposed side by side with the first stack structure, the second stack structure comprising at least one second chip; and
a second support structure penetrating through the molding layer and comprising: a plurality of second support pillars disposed around periphery of the second stack structure, wherein the second support structure has a height greater than that of the second stack structure.

7. The package structure of claim 6, wherein the plurality of first support pillars have a first density distribution on the periphery of the first stack structure, the plurality of second support pillars have a second density distribution on the periphery of the second stack structure, and wherein the first density distribution and the second density distribution are same or different.

8. The package structure of claim 1, wherein the package structure includes a redundancy region and a wiring region, and wherein,
the first support structure is located in at least one of the redundancy region or the wiring region.

9. The package structure of claim 1, wherein the first support structure has a mechanical strength greater than that of the molding layer.

10. The package structure of claim 1, wherein the first support structure comprises organic composite material, silicon-based material, or metal, and wherein
the molding layer comprises epoxy molding material.

11. A fabrication method of a package structure, comprising:
providing a substrate;
forming a first stack structure on the substrate that comprises at least one first chip;
forming a molding layer encapsulating the first stack structure on the substrate; and
forming a first support structure, wherein the first support structure penetrates through the molding layer and is located on periphery of the first stack structure, and the first support structure has a height greater than that of the first stack structure.

12. The fabrication method of claim 11, wherein the forming the first support structure comprises:
forming the first support structure on two opposite sides of the first stack structure in a first direction parallel to a plane in which the substrate is located.

13. The fabrication method of claim 12, wherein:
the first support structure is formed on two opposite sides of the first stack structure in the first direction, the first support structure has a size in a second direction smaller than or equal to that of the molding layer in the second direction, wherein the second direction intersects the first direction.

14. The fabrication method of claim 12, wherein the forming the first support structure comprises:
forming the first support structure on two opposite sides of the first stack structure in a second direction parallel to the plane in which the substrate is located,
wherein the second direction intersects the first direction.

15. The fabrication method of claim 14, wherein:
the first support structure is formed on two opposite sides of the first stack structure in the second direction, the first support structure has a size in the first direction smaller than or equal to that of the molding layer in the first direction.

16. The fabrication method of claim 11, wherein:
the forming the first support structure comprises:
forming a plurality of first support pillars disposed around the periphery of the first stack structure, wherein the first support structure comprises the plurality of first support pillars, and
the fabrication method further comprises:
forming a second stack structure disposed side by side with the first stack structure on the substrate, the second stack structure comprising at least one second chip; and
forming a second support structure, wherein the second support structure penetrates through the molding layer and comprises: a plurality of second support pillars disposed around periphery of the second stack structure, and the second support structure has a height greater than that of the second stack structure.

17. The fabrication method of claim 16, wherein the plurality of first support pillars have a first density distribution on the periphery of the first stack structure, the plurality of second support pillars have a second density distribution on the periphery of the second stack structure, and wherein the first density distribution and the second density distribution are same or different.

18. The fabrication method of claim 11, wherein the package structure comprises a redundancy region and a wiring region;
the forming the first support structure comprises:
forming the first support structure in at least one of the redundancy region or the wiring region.

19. The fabrication method of claim 11, wherein the first support structure has a mechanical strength greater than that of the molding layer.

20. The fabrication method of claim 11, wherein the first support structure comprises organic composite material, silicon-based material, or metal; and
the molding layer comprises epoxy molding material.
